(19) United States
(12) Patent Application Publication
(10) Pub. No.: US 2010/0081092 A1
(43) Pub. Date: Apr. 1, 2010

(54) METHOD FOR FABRICATING METAL INTERCONNECTION OF SEMICONDUCTOR DEVICE

(76) Inventor: Ki-Jun Yun, Suwon-si (KR)

Correspondence Address: SHERR & VAUGHN, PLLC, 620 HERNDON PARKWAY, SUITE 320, HERNDON, VA, 20170, US

(21) Appl. No.: 12/565,901

(22) Filed: Sep. 24, 2009

(30) Foreign Application Priority Data
Sep. 30, 2008 (KR) 10-2008-0096058

(51) Int. Cl. G03F 7/20; G03B 27/42

(52) U.S. Cl. 430/316; 355/53

(57) ABSTRACT

A method includes forming an interlayer dielectric layer including a contact plug over a semiconductor substrate, forming a metal layer, a hard mask layer, and an anti-reflection layer over the interlayer dielectric layer, forming a photoresist pattern over the anti-reflection layer, etching the anti-reflection layer in a primary etching process, using the photoresist pattern as an etching mask, to form an anti-reflection pattern, forming a first polymer layer over a surface of the anti-reflection pattern and the photoresist pattern by using polymer generated in the primary etching process, etching the hard mask layer in a secondary etching process, by using the anti-reflection pattern, the photoresist pattern, and the first polymer layer as an etching mask, to form a hard mask, and etching the metal layer in a tertiary etching process, by using the photoresist pattern, the anti-reflection pattern, the first polymer layer, and the hard mask as an etching mask, to form a metal interconnection. A first polymer layer is formed over the surface of the anti-reflection pattern and the photoresist pattern such that the design rule of the anti-reflection pattern is determined by polymer generated through the primary etching process.

The present application claims priority under 35 U.S.C. 119 to Korean Patent Application No. 10-2008-0096058 (filed on Sep. 30, 2008), which is hereby incorporated by reference in its entirety.

### BACKGROUND

To manufacture a semiconductor device, a metal interconnection process is required. The metal interconnection has various functions such as circuit connection, circuit matching, and signal phase changing. Metal interconnections have various sizes and shapes according to application fields.

An image sensor is one of the semiconductor devices which is highly integrated and manufactured to be small in size. Over time, the design rules of the image sensor have been decreased. For this reason, the aspect ratio of the metal interconnection has been increased. A metal interconnection is formed by first forming a metal layer, forming a photoresist pattern over the metal layer and then selectively etching the metal layer.

However, an etching process employing the photoresist pattern as a mask has a limitation when a plurality of metal interconnections are formed in a smaller image sensing device. Accordingly, a hard mask is used above the metal interconnection layer.

After forming a hard mask layer and a photoresist pattern over a metal interconnection layer, a hard mask is patterned according to the selectivity between the photoresist pattern and the hard mask layer. Then, the metal interconnection layer is etched by using the hard mask to form the metal interconnection.

The design rule and the surface profile of the metal interconnection can be determined according to the surface profile of the hard mask and the photoresist pattern formed above the hard mask. This is because polymer, which is generated when the hard mask is formed by using the photoresist pattern, is deposited over the sidewall of the hard mask or over the upper surface of the photoresist pattern. The polymer exerts an influence on the profile of the metal interconnection formed through the subsequent processes. For example, the thickness of the photoresist pattern and the hard mask may gradually increase along the downward direction by the polymer. If the metal interconnection is formed in such a state, the lower portion of the metal interconnection may be electrically connected to a neighboring metal interconnection, or the surface profile of the metal interconnection may be rough.

The surface profile of the metal interconnection is related to the electrical characteristics of a device. If the surface profile of the metal interconnection is not uniform, the resistance characteristic of the device may be degraded, reducing the life span of the device.

### SUMMARY

Embodiments relate to a method for fabricating a metal interconnection of a semiconductor device, capable of optimizing the surface profile of a hard mask by controlling an etching condition when the hard mask is formed by using a photoresist pattern, so that the electrical characteristic of the metal interconnection can be improved.

Embodiments relate to a method for fabricating a metal interconnection of a semiconductor device which includes forming an interlayer dielectric layer including a contact plug over a semiconductor substrate, forming a metal layer, a hard mask layer, and an anti-reflection layer over the interlayer dielectric layer, forming a photoresist pattern over the anti-reflection layer, forming an anti-reflection pattern by performing a primary etching process to etch the anti-reflection layer by using the photoresist pattern as an etching mask, forming a first polymer layer over a surface of the anti-reflection pattern and the photoresist pattern by using polymer generated in the primary etching process, forming a hard mask by performing a secondary etching process to etch the hard mask layer by using the anti-reflection pattern, the photoresist pattern, and the first polymer layer as an etching mask, and forming a metal interconnection by performing a tertiary etching process to etch the metal layer by using the photoresist pattern, the anti-reflection pattern, the first polymer layer, and the hard mask as an etching mask.

Embodiments relate to an apparatus configured to form an interlayer dielectric layer including a contact plug over a semiconductor substrate, form a metal layer, a hard mask layer, and an anti-reflection layer over the interlayer dielectric layer, form a photoresist pattern over the anti-reflection layer, etch the anti-reflection layer in a primary etching process, using the photoresist pattern as an etching mask, to form an anti-reflection pattern, form a first polymer layer over a surface of the anti-reflection pattern and the photoresist pattern by using polymer generated in the primary etching process, etch the hard mask layer in a secondary etching process, by using the anti-reflection pattern, the photoresist pattern, and the first polymer layer as an etching mask, to form a hard mask and etch the metal layer in a tertiary etching process, by using the photoresist pattern, the anti-reflection pattern, the first polymer layer, and the hard mask as an etching mask, to form a metal interconnection.

### DRAWINGS

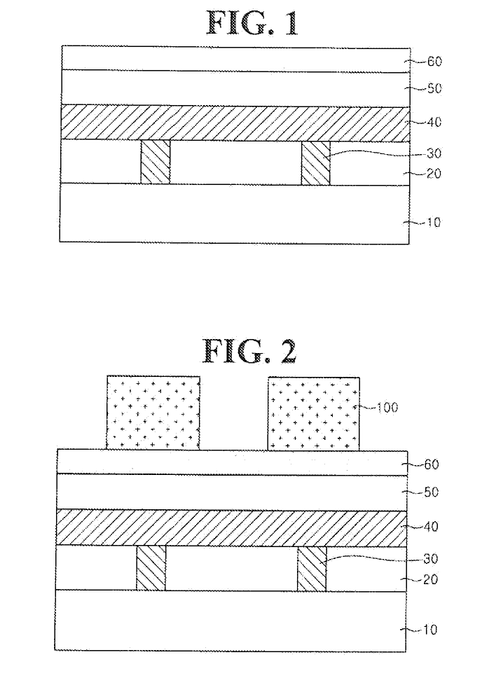

Example FIGS. 1 to 6 are sectional views showing a method for fabricating a metal interconnection of a semiconductor device according to embodiments.

### DESCRIPTION

Hereinafter, a method for fabricating a metal interconnection of a semiconductor device according to embodiments will be described with reference to accompanying drawings. Example FIGS. 1 to 6 are sectional views showing the method for fabricating the metal interconnection of the semiconductor device according to embodiments.

Referring to example FIG. 1, an interlayer dielectric layer 20, a metal layer 40, a hard mask layer 50, and an organic bottom anti-reflection layer (BARC) 60 may be formed over a semiconductor substrate 10. The semiconductor substrate 10 may include various devices, such as transistors. An interlayer dielectric layer 20, which may include an oxide layer or a nitride layer and a contact plug 30 passing through the interlayer dielectric layer 20, may be formed over the semiconductor substrate 10. The contact plug 30 passes through the interlayer dielectric layer 20 so that the contact plug 30 may be electrically connected with devices formed in the semiconductor substrate. For example, in an image sensor, a semiconductor device may be prepared in the form of a unit pixel including a photodiode and a transistor circuit.

Next, the metal layer 40 may be formed over the interlayer dielectric layer 20. The metal layer 40 may be electrically connected to the semiconductor device through the contact plug 30. The metal layer 40 may include various conductive materials such as metal, alloy, or silicide. For example, the metal layer 40 may include aluminum, copper, cobalt, or tungsten. An anti-oxidation layer including Ti/TiN may be formed on or below the metal layer 40.

Next, the hard mask layer 50 may be formed over the metal layer 40. The hard mask layer 50 may serve as a mask when etching the metal layer 40. The hard mask layer 50 may be one of an oxide layer, a nitride layer, and an oxynitride layer.

Then, the organic BARC layer 60 may be formed over the hard mask layer 50. The organic BARC layer 60 is designed to help prevent the critical dimension from varying during the metal interconnection process due to light diffracted and reflected from a lower layer. The organic BARC layer 60 can prevent light reflection from the lower layer by using an organic material that easily absorbs light in the wavelength band of an exposure light source. Accordingly, light is prevented from being reflected from the lower layer. For example, the organic BARC layer 60 may include a photoresist material.

Referring to example FIG. 2, a photoresist pattern 100 is formed over the organic BARC 60. The photoresist pattern 100 may be formed by coating ArF photoresist at a thickness of approximately 1600 Å to 2000 Å through a spin coating scheme. Then an exposure and development process may be performed on the resultant structure. The photoresist pattern 100 may cover the surface of the BARC 60 corresponding to an area for the metal interconnection, and expose a remaining area of the surface of the BARC 60.

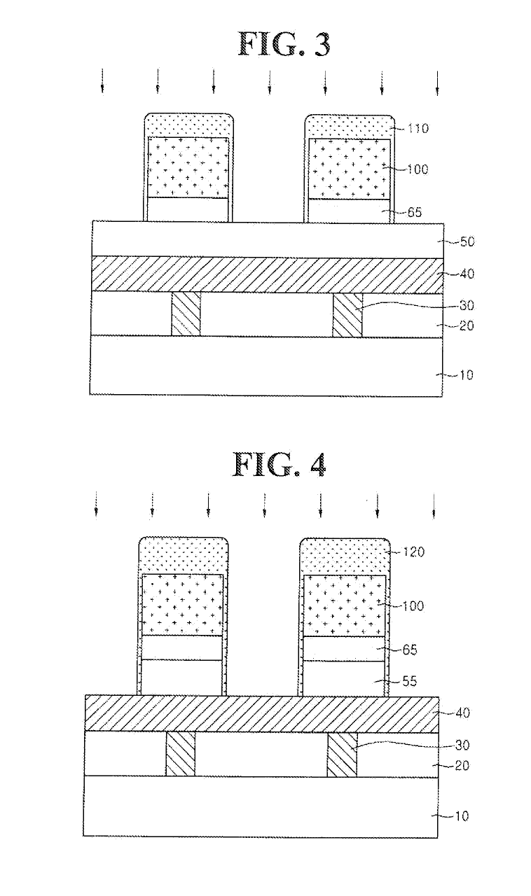

Referring to example FIG. 3, a BARC pattern 65 may be formed over the hard mask layer 50. The BARC pattern 65 may be formed after a primary etching process is performed with respect to the BARC layer 60 by using the photoresist pattern 100 as an etching mask. The BARC pattern 65 may determine a design rule of the metal interconnection. In other words, when the primary etching process is performed with respect to the BARC layer 60, polymer is generated. This polymer may be deposited over the surface of the photoresist pattern 100 and the sidewall of the BARC pattern 65, so that a first polymer layer 110 is formed. For example, the first polymer layer 110 may include a compound containing C-C or C-F.

In particular, the first relatively thick polymer layer 110 may be deposited over the surface of the photoresist pattern 100. For example, the first polymer layer 110 may be formed over the sidewall and the surface of the photoresist pattern 100 in the thickness ratio of between 1:3 and 1:10.

CF₄, Ar and O₂ may be used as etching gas in the primary etching process to form the BARC pattern 65. In particular, to form a structure according to a required design rule of the BARC pattern 65, the etching gas of CF₄, Ar and O₂ must be used.

For example, the BARC pattern 65 may be formed by applying CF₄, Ar and O₂ at flow rates of 65 sccm to 95 sccm, 300 sccm to 360 sccm, and 9 sccm to 15 sccm, respectively. The optimum condition to form the BARC pattern 65 may be, for example, achieved when CF₄, Ar and O₂ are applied at flow rates of approximately 80 sccm, 300 sccm, and 12 sccm, respectively.

As described above, through the primary etching process, the BARC pattern 65 may be formed, and the first polymer layer 110 may be formed over the surface of the photoresist pattern 100 and the BARC pattern 65. The first polymer layer 110 may be uniformly formed over the surface of the photoresist pattern 100, so that the BARC pattern 65, the photoresist pattern 100, and the first polymer layer 110 may have a uniform surface profile.

If the CF₄, Ar and O₂ are not applied in the primary etching process, but different gas is applied, the adjustment of the design rule of the BARC pattern 65 may be impossible. Accordingly, only the CF₄, Ar and O₂ may be used to form the BARC pattern 65. After the BARC pattern 65 and the first polymer layer 110 are formed through the primary etching process so that the design rule of the BARC pattern 65 is determined, the design rule of the metal interconnection may be determined through the subsequent process, based on the design rule of the BARC pattern 65.

Referring to example FIG. 4, a hard mask 55 may be fanned over the metal layer 40. The hard mask 55 may be formed by performing a secondary etching process using the photoresist pattern 100 and the BARC pattern 65 as an etching mask.

The hard mask 55 can determine the surface profile of the metal interconnection. This is because the amount and the deposition direction of the polymer can be determined when the secondary etching process is performed on the hard mask layer 50 by using the photoresist pattern 100 and the BARC pattern 65. Accordingly, a second polymer layer 120 may be formed over the surface of the photoresist pattern 100, the BARC pattern 65, and the hard mask 55 to pre-determine the surface profile of the metal interconnection formed through the subsequent process. For example, the polymer layer 120 may include a compound containing C-C or C-F.

When the secondary etching process is performed to form the hard mask 55, etching gas of C₅F₈, Ar and O₂ may be used. In addition, etching gas of C₄F₈, Ar and O₂ may be used in the secondary etching process.

For example, the hard mask 55 may be formed under etching conditions in which C₅F₈, Ar and O₂ are applied at flow rates of 12 sccm to 18 sccm, 800 sccm to 960 sccm, and 9 sccm to 15 sccm, respectively, source power is supplied in the range of 1400 W to 2400 W at a frequency of 27 MHz±10, and bias power is supplied in the range of 1600 W to 2500 W at a frequency of 5 MHz±3. The optimum condition to form the BARC pattern 65 may be, for example, achieved when CF₄, Ar and O₂ are applied at a flow rate of approximately 80 sccm, 300 sccm, and 12 sccm, respectively, approximately 1500 W of source power is supplied at a frequency of approximately 27 MHz, and approximately 1700 W of bias power is supplied at a frequency of approximately 2 MHz

As described above, the hard mask 55 may be formed through the secondary etching process, and the second polymer layer 120 may be formed over the surface of the photoresist pattern 100, the BARC pattern 65, and the hard mask 55.

In particular, the amount and the deposition direction of the second polymer layer 120 can be adjusted by the secondary etching process. Accordingly, the surface profile of the hard mask 55, the BARC pattern 65, the photoresist pattern 100, and the second polymer layer 120 can be evenly formed. Accordingly, the surface profile of the metal interconnection formed through the subsequent process can be determined. Etching gas used in the primary and secondary processes may not exceed about ±20% of the optimum condition.

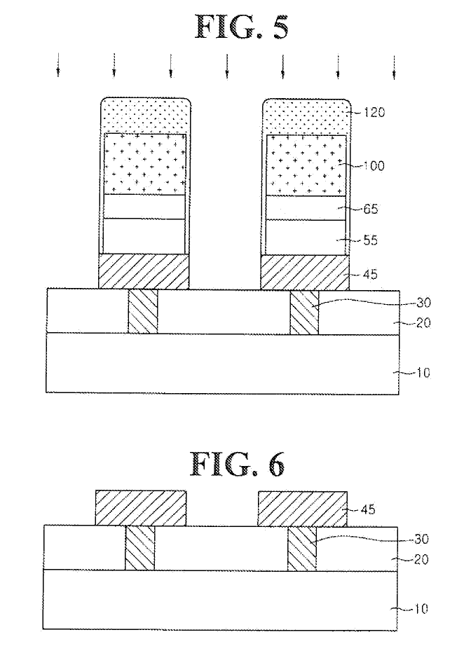

Referring to example FIGS. 5 and 6, a metal interconnection 45 may be formed over the interlayer dielectric layer 20. The metal interconnection 45 may be formed through an etching process employing the hard mask 55, the BARC pattern 65, the photoresist pattern 100, and the second polymer layer 120 as an etching mask. Thereafter, the hard mask 55, the BARC pattern 65, the photoresist pattern 100, and the second polymer layer 120 may be removed though an etching process.

As described above, the BARC pattern 65 is formed through the primary etching process for the photoresist pattern 100 so that the design rule of the metal interconnection 45 is determined. Then, the hard mask 55 is formed by the photoresist pattern 100 and the BARC pattern 65 so that the surface profile of the metal interconnection 45 is determined. Accordingly, in the final stage, the metal interconnection 45 can be formed with a required design rule and a uniform surface profile.

Accordingly, the electric characteristic of the metal interconnection 45 is improved, so that device quality can be enhanced. In addition, since the process margin for the hard mask 55 and the BARC pattern 65 can be ensured, problems such as variations in equipment and etching conditions can be checked and prevented.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an interlayer dielectric layer including a contact plug over a semiconductor substrate;
forming a metal layer, a hard mask layer, and an anti-reflection layer over the interlayer dielectric layer;
forming a photoresist pattern over the anti-reflection layer;
etching the anti-reflection layer in a primary etching process, using the photoresist pattern as an etching mask, to form an anti-reflection pattern;
forming a first polymer layer over a surface of the anti-reflection pattern and the photoresist pattern by using polymer generated in the primary etching process;
etching the hard mask layer in a secondary etching process, by using the anti-reflection pattern, the photoresist pattern, and the first polymer layer as an etching mask, to form a hard mask; and
etching the metal layer in a tertiary etching process, by using the photoresist pattern, the anti-reflection pattern, the first polymer layer, and the hard mask as an etching mask, to form a metal interconnection.

2. The method of claim 1, including forming a second polymer layer, over a surface of the first polymer layer and the hard mask, by using polymer generated in the secondary etching process.

3. The method of claim 1, wherein CF₄, O₂ and Ar are used in the primary etching process.

4. The method of claim 3, wherein CF₄ is applied in a range of 65 sccm to 95 sccm, O₂ is applied in a range of 9 sccm to 15 sccm, and Ar is applied in a range of 300 sccm to 360 sccm.

5. The method of claim 1, wherein C₅F₈, O₂ and Ar are used in the secondary etching process.

6. The method of claim 1, wherein C₄F₈, O₂ and Ar are used in the secondary etching process.

7. The method of claim 5, wherein C₅F₈ is applied in a range of 12 sccm to 18 sccm, O₂ is applied in a range of 9 sccm to 15 sccm, and Ar is applied in a range of 800 sccm to 960 sccm.

8. The method of claim 5, wherein source power is supplied in a range of 1400 W to 1600 W at a frequency of 10 MHz to 37 MHz, and bias power is supplied to in a range of 1600 W to 1800 W at a frequency of 1 MHz to 5 MHz when the secondary etching process is performed.

9. The method of claim 2, wherein the first and second polymer layers include C-C compound or C-F compound.

10. The method of claim 1, wherein the photoresist pattern is formed by using ArF photoresist.

11. The method of claim 3, wherein an amount of CF₄, O₂ and Ar are used in a range of ±20% when the primary etching process is performed.

12. The method of claim 7, wherein an amount of C₅F₈, O₂ and Ar used in the secondary etching process is controlled in a range of ±20%.

13. The method of claim 3, wherein CF₄ is applied at approximately 80 sccm, O₂ is applied at approximately 12 sccm, and Ar is applied at approximately 300 sccm.

14. An apparatus configured to:
form an interlayer dielectric layer including a contact plug over a semiconductor substrate;
form a metal layer, a hard mask layer, and an anti-reflection layer over the interlayer dielectric layer;
form a photoresist pattern over the anti-reflection layer;
etch the anti-reflection layer in a primary etching process, using the photoresist pattern as an etching mask, to form an anti-reflection pattern;
form a first polymer layer over a surface of the anti-reflection pattern and the photoresist pattern by using polymer generated in the primary etching process;
etch the hard mask layer in a secondary etching process, by using the anti-reflection pattern, the photoresist pattern, and the first polymer layer as an etching mask, to form a hard mask; and
etch the metal layer in a tertiary etching process, by using the photoresist pattern, the anti-reflection pattern, the first polymer layer, and the hard mask as an etching mask, to form a metal interconnection.

15. The apparatus of claim 14, configured to form a second polymer layer, over a surface of the first polymer layer and the hard mask, by using polymer generated in the secondary etching process.

16. The apparatus of claim 14, configured to use CF₄, O₂ and Ar in the primary etching process.

17. The apparatus of claim 16, configured to apply CF₄ in a range of 65 sccm to 95 sccm, O₂ in a range of 9 sccm to 15 sccm, and Ar is applied in a range of 300 sccm to 360 sccm.

18. The apparatus of claim 14, configured to use C₅F₈, O₂ and Ar in the secondary etching process.

19. The apparatus of claim 14, configured to use C₄F₈, O₂ and Ar in the secondary etching process.

20. The apparatus of claim 18, configured to apply C₅F₈ in a range of 12 sccm to 18 sccm, to apply O₂ in a range of 9 sccm to 15 sccm, and to apply Ar in a range of 800 sccm to 960 sccm.
